(19) United States
(12) Patent Application Publication
(10) Pub. No.: US 2026/0075973 A1
(43) Pub. Date: Mar. 12, 2026

(54) SEMICONDUCTOR PACKAGE

(71) Applicant: Samsung Electronics Co., Ltd., Suwon-si (KR)

(72) Inventors: Hyongook KIM, Suwon-si (KR); Junyoung KO, Suwon-si (KR)

(73) Assignee: Samsung Electronics Co., Ltd., Suwon-si (KR)

(21) Appl. No.: 19/073,456

(22) Filed: Mar. 7, 2025

(30) Foreign Application Priority Data
Sep. 10, 2024 (KR) 10-2024-0122864

(51) Int. Cl. H10F 39/00

(52) U.S. Cl. CPC H10F 39/8057; H10F 39/804; H10F 39/811; H10F 39/011

(57) ABSTRACT

A semiconductor package may include a package substrate, an image sensor chip on the package substrate, a first adhesion layer, a transparent cover on the first adhesion layer, and a molding member on the package substrate. The image sensor chip may include an active pixel sensor (APS) region, a non-active pixel sensor (non-APS) region at least partially surrounding the APS region, and a pad region at least partially surrounding the non-APS region. The image sensor chip may include a blocking structure on the non-APS region. An inner sidewall of the blocking structure may be at a boundary between the APS region and the non-APS region. The first adhesion layer may be on the non-APS region and the pad region of the image sensor chip. The transparent cover may be on the first adhesion layer. The molding member may cover sidewalls of the image sensor chip and the first adhesion layer.

### CROSS-REFERENCE TO RELATED APPLICATION

This application claims priority under 35 U.S.C. §119 to Korean Patent Application No. 10-2024-0122864, filed on Sep. 10, 2024 in the Korean Intellectual Property Office (KIPO), the contents of which are herein incorporated by reference in their entirety.

### BACKGROUND

### 1. Field

Example embodiments relate to a semiconductor package. More particularly, example embodiments relate to a semiconductor package including an image sensor chip.

2. Description of the Related Art

After manufacturing a package including an image sensor chip, a visual inspection is performed. If an abnormal substance is detected in the image sensor chip, the package is judged as a defective product. However, if the abnormal substance is very small, the detection of the abnormal substance is not easy.

### SUMMARY

Example embodiments provide a semiconductor package having enhanced electrical characteristics.

According to example embodiments, a semiconductor package may include a package substrate, an image sensor chip on the package substrate, a first adhesion layer, a transparent cover on the first adhesion layer, and a molding member on the package substrate. The image sensor chip may include an active pixel sensor (APS) region, a non-active pixel sensor (non-APS) region at least partially surrounding the APS region, and a pad region at least partially surrounding the non-APS region. The image sensor chip may include a blocking structure on the non-APS region, and an inner sidewall of the blocking structure adjacent to the APS region being at a boundary between the APS region and the non-APS region. The first adhesion layer may be on the non-APS region of the image sensor chip and the pad region of the image sensor chip. The molding member may cover a sidewall of the image sensor chip and a sidewall of the first adhesion layer.

According to example embodiments, a semiconductor package may include a package substrate, an image sensor chip on the package substrate, an adhesion layer, a transparent cover on the adhesion layer, and a molding member on the package substrate. The image sensor chip may include a first region, a second region at least partially surrounding the first region, and a third region at least partially surrounding the second region. The image sensor chip may include a blocking structure. A first sidewall of the blocking structure may be aligned with an edge of the first region of the image sensor in a vertical direction and the vertical direction may be perpendicular to an upper surface of the package substrate. Active pixels may be in the first region. No active pixels may be in the second region. A chip pad may be in the third region. The adhesion layer may be on the second region and the third region of the image sensor chip. The adhesion layer may contact the blocking structure. The molding member may cover a sidewall of the image sensor chip and a sidewall of the adhesion layer.

According to example embodiments, a semiconductor package may include a package substrate including a substrate pad, a first adhesion layer on the package substrate, an image sensor chip bonded to the first adhesion layer, a bonding wire, a second adhesion layer, a transparent cover on the second adhesion layer, and a molding member on the package substrate. The image sensor chip may include an active pixel sensor (APS) region, a non-active pixel sensor (non-APS) region at least partially surrounding the APS region, and a pad region at least partially surrounding the non-APS region. The image sensor chip may include a blocking structure on the non-APS region and a chip pad in the pad region. An inner sidewall of the blocking structure may be adjacent to the APS region and may be at a boundary between the APS region and the non-APS region. The bonding wire may contact the chip pad and the substrate pad. The second adhesion layer may be on the non-APS region and the pad region of the image sensor chip. The second adhesion layer may cover an upper surface of the chip pad and a portion of the bonding wire. The molding member may cover a sidewall of the first adhesion layer, a sidewall of the image sensor chip, and a sidewall of the second adhesion layer. The molding member may cover a portion of the bonding wire.

An image sensor in the semiconductor package according to example embodiments may include the blocking structure in the non-APS region surrounding the APS region, so that the adhesion layer in the pad region may also be formed in the non-APS region. Thus, defect generated by the movement of an abnormal substance in the non-APS region to the APS region may be limited and/or prevented, and an additional manual visual inspection process for detecting the defect may be skipped so that the manufacturing time of the semiconductor package may be reduced.

### BRIEF DESCRIPTION OF THE DRAWINGS

FIG. 1 is a cross-sectional view illustrating a semiconductor package in accordance with example embodiments.

FIGS. 2 to 10 are plan views and cross-sectional views illustrating a method of manufacturing a semiconductor package in accordance with example embodiments.

FIGS. 11 to 13 are cross-sectional views illustrating semiconductor packages in accordance with example embodiments.

### DETAILED DESCRIPTION OF EXAMPLE EMBODIMENTS

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereinafter, example embodiments will be explained in detail with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Hereinafter, a direction substantially parallel to an upper surface of a wafer, a panel or a substrate may be referred to as a horizontal direction, and a direction substantially perpendicular to the upper surface of the wafer, the panel or the substrate may be referred to as a vertical direction.

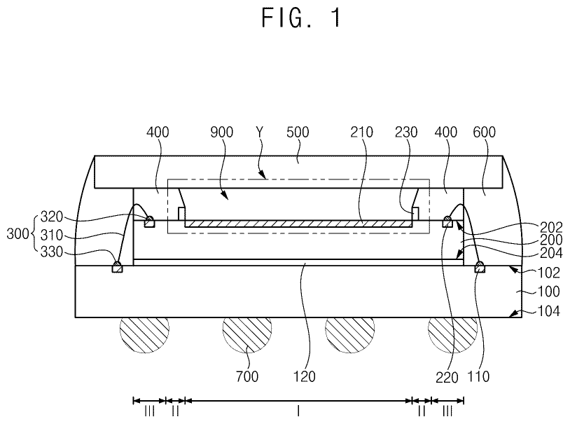

FIG. 1 is a cross-sectional view illustrating a semiconductor package in accordance with example embodiments.

Referring to FIG. 1, the semiconductor package may include a package substrate 100, an image sensor chip 200, first and second adhesion layers 120 and 400, a bonding wire 300, a transparent cover 500, a molding member 600 and a conductive connection member 700.

The package substrate 100 may be, e.g., a printed circuit board (PCB), which may be a multi-layered circuit board including various circuit patterns. The package substrate 100 may include first and second surfaces 102 and 104 opposite to each other in the vertical direction, and may include a substrate pad 110 adjacent to the first surface 102.

In example embodiments, the package substrate 100 may have a shape of a rectangle in a plan view, and a plurality of substrate pads 110 may be spaced apart from each other in the horizontal direction adjacent to sides of the rectangle in a plan view, however, inventive concepts are not limited thereto.

The image sensor chip 200 may include first and second surfaces 202 and 204 opposite to each other in the vertical direction. The first surface 202 of the image sensor chip 200 may be an active surface in which active pixels are disposed, and the second surface 204 of the image sensor chip 200 may be an inactive surface in which no active pixels are disposed.

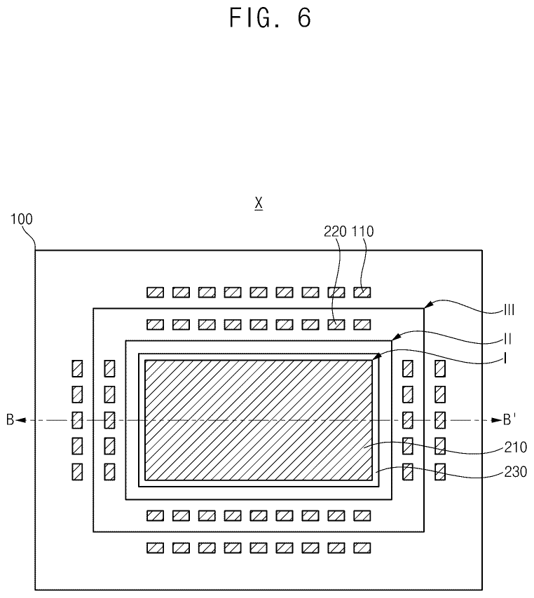

Referring to FIG. 1 together with FIG. 6, in example embodiments, the image sensor chip 200 may include a first region I, a second region II at least partially surrounding the first region I, and a third region III at least partially surrounding the second region II. For example, in a plan view, the first region I may have a shape of a rectangle, and each of the second and third regions II and III may have a shape of a rectangular ring.

The first region I may be an active pixel sensor (APS) region in which active pixels are disposed, the second region II may be an optical black (OB) region in which OB pixels are disposed or a non active pixel sensor (non-APS) region, and the third region III may be a pad region or a peripheral circuit region in which chip pads and/or through vias are disposed.

In example embodiments, a blocking structure 230 may be disposed on the first surface 202 in the second region II of the image sensor chip 200. In example embodiments, the blocking structure 230 may have a shape of a rectangular ring surrounding the first region I of the image sensor chip 200 in a plan view. In an example embodiment, an inner sidewall of the blocking structure 230 may be disposed at a boundary between the first and second regions I and II of the image sensor chip 200, and an outer sidewall of the blocking structure 230 may be disposed at an inside of the second region II of the image sensor chip 200.

That is, the blocking structure 230 may not overlap the first region I of the image sensor chip 200 in the vertical direction, and may overlap a portion of the second region II adjacent to the first region I of the image sensor chip 200 in the vertical direction. The inner sidewall of the blocking structure 230 may be aligned with the boundary between the first and second regions I and II of the image sensor chip 200, that is, an edge of the first region I of the image sensor chip 200.

In an example embodiment, the blocking structure 230 may have a single-layered structure including an insulating material, e.g., silicon oxide, silicon nitride, etc., which is shown in FIG. 1. Alternatively, the blocking structure 230 may have a multi-layered structure having a conductive pattern including a metal, e.g., aluminum and an insulation pattern covering a surface of the conductive pattern and including an insulating material.

A chip pad 220 may be disposed at a portion adjacent to the first surface 202 in the third region III of the image sensor chip 200. In example embodiments, a plurality of chip pads 220 may be spaced apart from each other in the horizontal direction in the third region III of the image sensor chip 200, however, inventive concepts are not limited thereto. The chip pad 220 may include a metal, e.g., copper, aluminum, nickel, gold, etc.

The first adhesion layer 120 may be attached to the second surface 204 of the image sensor chip 200, and may be bonded to the first surface 102 of the package substrate 100. The first adhesion layer 120 may include, e.g., die attach film (DAF), non-conductive film (NCF), etc.

The bonding wire 300 may contact the chip pad 220 and a corresponding one of the substrate pads 110. A plurality of bonding wires 300 may be spaced apart from each other in the horizontal direction.

Each of the bonding wires 300 may include a first contacting portion 320 that may contact an upper surface of the chip pad 220, a second contacting portion 330 that may contact an upper surface of the substrate pad 110, and a vertical extension portion that may extend in the vertical direction and may be connected to the first and second contacting portions 320 and 330.

The second adhesion layer 400 may cover the first surface 202 in the second and third regions II and III of the image sensor chip 200, and may contact the outer sidewall of the blocking structure 230. Thus, the second adhesion layer 400 may have a shape of a rectangular ring that may surround the blocking structure 230. In example embodiments, an upper surface of the second adhesion layer 400 may be higher than an upper surface of the blocking structure 230.

The second adhesion layer 400 may cover the chip pad 220 in the third region III of the image sensor chip 200, and an end portion of the vertical extension portion 310 and the first contacting portion 320 of the bonding wire 300.

The second adhesion layer 400 may include, e.g., glue.

The transparent cover 500 may be bonded to the upper surface of the second adhesion layer 400. In example embodiments, the transparent cover 500 may have a shape of a rectangular plate, and a planar area of the transparent cover 500 may be greater than a planar area of the image sensor chip 200. The transparent cover 500 may include, e.g., transparent glass, transparent ceramic, etc.

A cavity 900 including, e.g., air or in a vacuum state may be disposed between the image sensor chip 200, the transparent cover 500 and the second adhesion layer 400.

The molding member 600 may be disposed on the first surface 102 of the package substrate 100, and may cover sidewalls of the first and second adhesion layers 120 and 400 and the image sensor chip 200, a lower sidewall of the transparent cover 500, and the bonding wire 300. The molding member 600 may include, e.g., epoxy molding compound (EMC).

The conductive connection member 700 may be disposed on the second surface 104 of the package substrate 100, and may be electrically connected to an outer substrate. The conductive connection member 700 may include, e.g., a conductive bump or a conductive ball.

In the semiconductor package, the image sensor chip 200 may include the blocking structure 230 on the first surface 202 at the portion of the second region II adjacent to the first region I of the image sensor chip 200, and may limit and/or prevent the second adhesion layer 400 being coated into the first region I of the image sensor chip 200. Thus, the second adhesion layer 400 may not permeate into an inside of the first region I of the image sensor chip 200, so that the second adhesion layer 400 may be formed not only in the third region III of the image sensor chip 200, which is spaced apart from the first region I of the image sensor chip 200, but also in the second region II of the image sensor chip 200, which may surround the first region I of the image sensor chip 200.

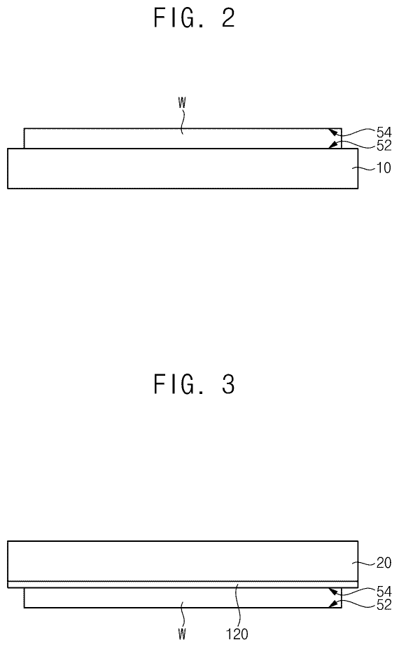

As illustrated below with reference to FIGS. 2 to 10, the abnormal substances may not move from the second region II of the image sensor chip 200 into the first region I of the image sensor chip 200 to cause defect.

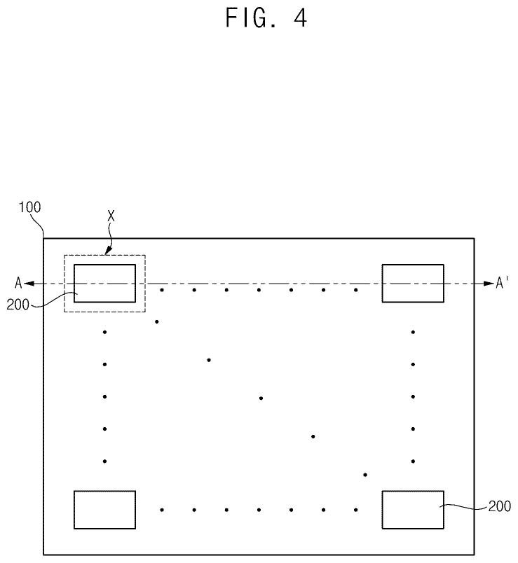

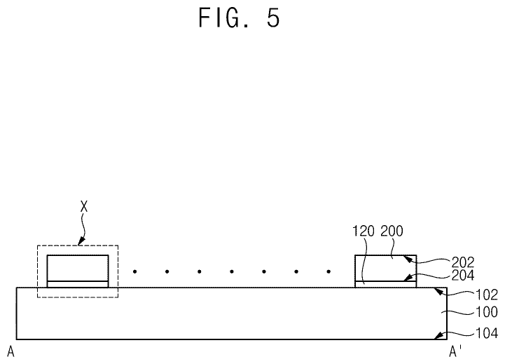

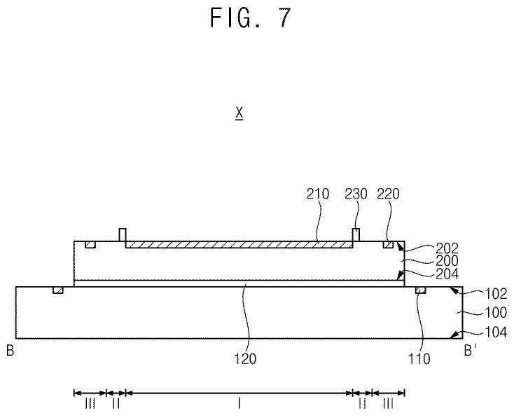

FIGS. 2 to 10 are plan views and cross-sectional views illustrating a method of manufacturing a semiconductor package in accordance with example embodiments. Particularly, FIGS. 4, 6 and 8 are the plan views, and FIGS. 2-3, 5, 7 and 9-10 are the cross-sectional views. FIG. 5 is a cross-sectional view taken along line A-A′ of FIG. 4, and FIGS. 7 and 9-10 are cross-sectional views taken alone lines B-B′ of corresponding plan views, respectively. FIGS. 6 to 10 are drawings about region X of FIGS. 4 and 5.

Referring to FIG. 2, a wafer W including first and second surfaces 52 and 54 opposite to each other in the vertical direction may be mounted onto a first ring frame 10.

In example embodiments, the wafer W may include a substrate having a plurality of die regions and a scribe lane region surrounding the die regions, and image sensors may be disposed in each of the die regions of the substrate.

The substrate may include a semiconductor material, e.g., silicon, germanium, silicon-germanium (Si—Ge), etc., or a III-V compound, e.g., GaP, GaAs, GaSb, etc. The first surface 52 of the wafer W that may contact an upper surface of the first ring frame 10 may be an active surface in which active pixels are disposed, and the second surface 54 of the wafer W may be an inactive surface in which no active pixels are disposed. In an example embodiment, a temporary adhesion layer may be disposed on the upper surface of the first ring frame 10, however, inventive concepts are not limited thereto.

A portion of the wafer W adjacent to the second surface 54 thereof may be removed by, e.g., a grinding process so that a thickness of the wafer W in the vertical direction may be reduced.

Referring to FIG. 3, a second ring frame 20 may be bonded to the wafer W1 through a first adhesion layer 120 attached to a lower surface of the second ring frame 20, and the wafer W may be separated from the first ring frame 10.

In example embodiments, the first adhesion layer 120 may contact the second surface 54 of the wafer W, which is the inactive surface of the wafer W.

Referring to FIGS. 4 to 7, after flipping the second ring frame 20, for example, a sawing process may be performed along the scribe lane region of the wafer W so that the wafer W may be divided into a plurality of image sensor chips 200, and each of the image sensor chips 200 may be picked up from the second ring frame 20 to be mounted onto a package substrate 100.

The package substrate 100 may include first and second surfaces 102 and 104 opposite to each other in the vertical direction, and may include a substrate pad 110 adjacent to the first surface 102 thereof.

Each of the image sensor chips 200 may include first and second surfaces 202 and 204 opposite to each other in the vertical direction, and the first surface 202 may be an active surface and the second surface 204 may be an inactive surface.

In example embodiments, each of the image sensor chips 200 may include a first region I, a second region II at least partially surround the first region I, and a third region III at least partially surround the second region II.

The first region I may be an active pixel sensor (APS) region in which active pixels are disposed, the second region II may be an optical black (OB) region in which OB pixels are disposed or a non-active pixel sensor (non-APS) region, and the third region III may be a pad region or a peripheral circuit region in which chip pads and/or through vias are disposed.

A blocking structure 230 may be disposed in the second region II of each of the image sensor chips 200. In example embodiments, the blocking structure 230 may have a shape of a rectangular ring surrounding the first region I of the image sensor chip 200 in a plan view. In an example embodiment, an inner sidewall of the blocking structure 230 may be disposed at a boundary between the first and second regions I and II of the image sensor chip 200, and an outer sidewall of the blocking structure 230 may be disposed at an inside of the second region II of the image sensor chip 200. The image sensor chip 200 may include a pixel circuit 210 including a plurality of active pixels on a region of the first surface 202 of the image sensor chip 202 surrounded by the blocking structure 230.

A chip pad 220 may be disposed in the third region III of each of the image sensor chips 200. In example embodiments, a plurality of chip pads 220 may be spaced apart from each other in the third region III, however, inventive concepts are not limited thereto.

In example embodiments, during the sawing process, the first adhesion layer 120 attached to the second ring frame 20 may also be cut, and may be attached to the second surface 204 of each of the image sensor chips 200 to be picked up.

In example embodiments, each of the image sensor chips 200 may be mounted onto the first surface 102 of the package substrate 100 through the first adhesion layer 120, and, for example, a curing process may be performed on the first adhesion layer 120 so that each of the image sensor chips 200 may be bonded to the first surface 102 of the package substrate 100.

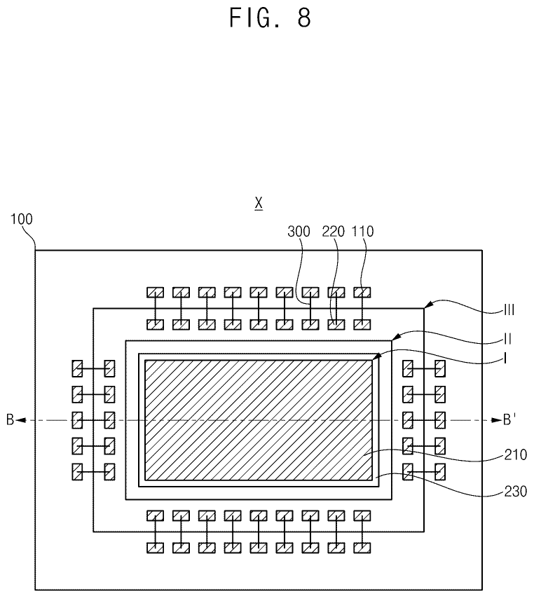

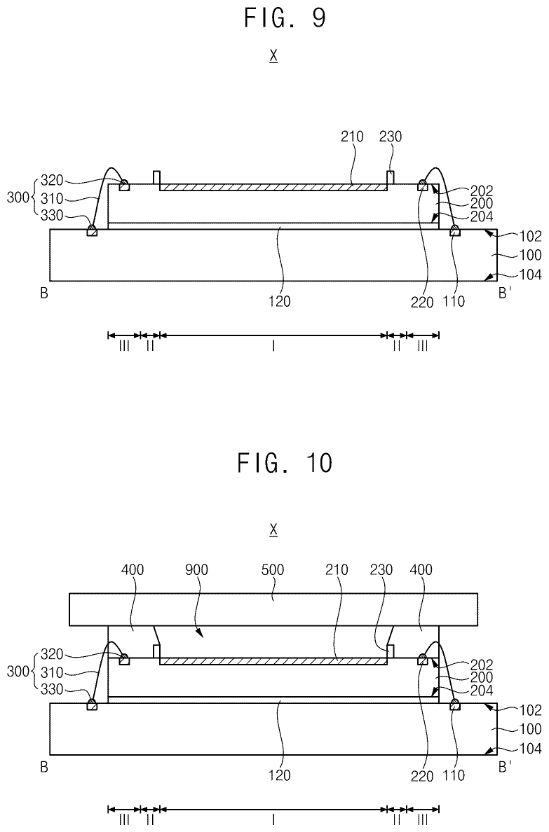

Referring to FIGS. 8 and 9, a wire bonding process may be performed to form a bonding wire 300 contacting the chip pad 220 of the image sensor chip 200 and the substrate pad 110 of the package substrate 100, so that the chip pad 220 and the substrate pad 110 may be electrically connected to each other.

In example embodiments, a plurality of bonding wires 300 may be formed to contact the chip pads 220 and corresponding substrate pads 110, respectively. Each of the bonding wires 300 may include a first contacting portion 320 that may contact an upper surface of the chip pad 220, a second contacting portion 330 that may contact an upper surface of the substrate pad 110, and a vertical extension portion 310 that may extend in the vertical direction to be connected to the first and second contacting portions 320 and 330.

Referring to FIG. 10, a second adhesion layer 400 may be coated to cover the second and third regions II and III of the image sensor chip 200, a transparent cover 500 may be mounted onto the second adhesion layer 400, and a curing process may be performed on the second adhesion layer 400, so that the transparent cover 500 may be bonded to an upper surface of the second adhesion layer 400.

In example embodiments, the second adhesion layer 400 may be blocked by the blocking structure 230 in the second region II of the image sensor chip 200 so as not to be coated in the first region I of the image sensor chip 200. The second adhesion layer 400 may contact an outer sidewall of the blocking structure 230, and an upper surface of the second adhesion layer 400 may be higher than an upper surface of the blocking structure 230.

The second adhesion layer 400 may cover the chip pad 220 in the third region III of the image sensor chip 200, and an end portion of the vertical extension portion 310 and the first contacting portion 320 of the bonding wire 300.

In example embodiments, the transparent cover 500 may have a shape of a rectangular plate, and a planar area of the transparent cover 500 may be greater than a planar area of the image sensor chip 200.

Referring to FIG. 1 again, a molding member 600 may be formed on the first surface 102 of the package substrate 100, a conductive connection member 700 may be formed on the second surface 104 of the package substrate 100, and a singulation process may be performed on the package substrate 100 and a structure thereon to manufacture a plurality of semiconductor packages.

The molding member 600 may be formed on the package substrate 100, and may cover sidewalls of the first and second adhesion layers 120 and 400 and the image sensor chip 200, a lower sidewall of the transparent cover 500, and the bonding wire 300.

A first automatic visual inspection (AVI) process may be performed on the semiconductor package. In example embodiments, if an abnormal substance having, e.g., a size equal to or greater than about 6 um exists in the first region I of the image sensor chip 200, the abnormal substance may be detected by the first AVI process. If no abnormal substance is detected, the semiconductor package may be judged as a good product.

A test process may be performed on the semiconductor package, and if the image sensor chip 200 included in the semiconductor package is operated well, the semiconductor package may be judged as a good product. Additionally, if an abnormal substance having, e.g., a size equal to or greater than about 2 um exists in the first region I of the image sensor chip 200, the abnormal substance may be detected by the test process. If no abnormal substance is detected, the semiconductor package may be judged as a good product.

A second AVI process may be further performed on the semiconductor package. In example embodiments, if an abnormal substance having, e.g., a size equal to or greater than about 6 um exists in the first region I of the image sensor chip 200, the abnormal substance may be detected by the second AVI process. If no abnormal substance is detected, the semiconductor package may be judged as a good product.

Poor products may be filtered by the first and second AVI processes and the test process, so that only good products may be delivered.

If the image sensor chip 200 does not include the blocking structure 230, in order to limit and/or prevent the second adhesion layer 400 from being coated into the first region I of the image sensor chip 200, the second adhesion layer 400 may not be coated into the second region II of the image sensor chip 200 but may be coated only into the third region III of the image sensor chip 200.

However, if an abnormal substance having, e.g., a size less than about 6 um and greater than about 2 um exists in the second region II of the image sensor chip 200, the abnormal substance may not be detected by the first and second AVI processes and the test process.

If the abnormal substance exists only in the second region II of the image sensor chip 200 and does not move into the first region I of the image sensor chip 200 after the test process, the abnormal substance may not cause any problem. However, the abnormal substance may move form the second region II to the first region I of the image sensor chip during the test process, and in this case, the semiconductor package may be a poor product even though it is judged as a good product.

Thus, in order to filter the poor product generated by the movement of the abnormal substance, a manual visual inspection (MVI) process may be further performed. The MVI process needs a large amount of time, which may increase the manufacturing time of the semiconductor package.

However, in example embodiments, the image sensor chip 200 may include the blocking structure 230 so that the second adhesion layer 400 may be limited and/or prevented from moving into the first region I of the image sensor chip 200. Thus, the second adhesion layer 400 may be coated to cover the second region II adjacent to the first region I of the image sensor chip 200, and thus the possibility of existence of an abnormal substance in the second region II of the image sensor chip 200 may be limited and/or completely prevented.

As a result, no abnormal substance may move from the second region II into the first region I of the image sensor chip 200 after the test process, so that an additional MVI process may not be performed, which may reduce the manufacturing time of the semiconductor package.

The blocking structure 230 may be formed on the wafer W before the wafer W is singulated into a plurality of image sensor chips 200 by the sawing process, however, inventive concepts are not limited thereto.

For example, after the wafer W is singulated into a plurality of image sensor chips 200 by the sawing process, before coating the second adhesion layer 400 onto each of the image sensor chips 200, the blocking structure 230 may be formed in the second region II of each of the image sensor chips 200. In this case, the blocking structure 230 may be formed by similar way in which the second adhesion layer 400 is coated onto each of the image sensor chips 200.

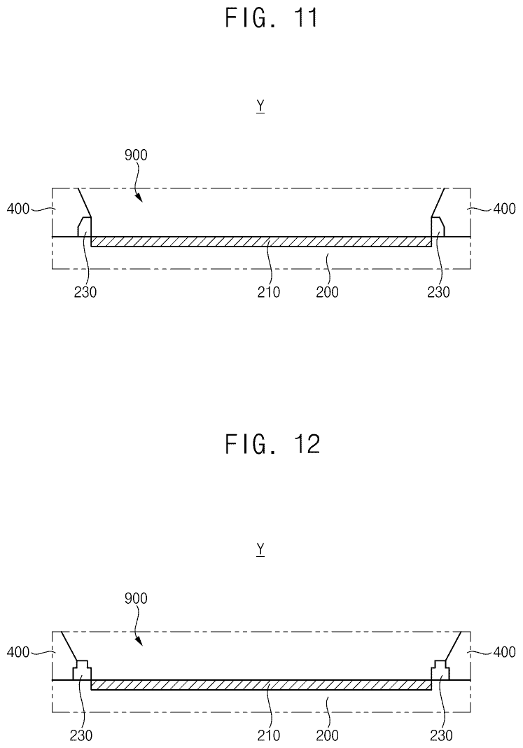

FIGS. 11 to 13 are cross-sectional views illustrating semiconductor packages in accordance with example embodiments, which may correspond to region Y in FIG. 1.

Each of the semiconductor packages may be substantially the same as or similar to that of FIG. 1, except for the shape of the blocking structure, and thus repeated explanations are omitted herein.

Referring to FIG. 11, the inner sidewall of the blocking structure 230 may extend in the vertical direction, while the outer sidewall of the blocking structure 230 may include a lower portion extending in the vertical direction and an upper portion sloped with respect to the vertical direction.

Alternatively, an entire portion of the outer sidewall of the blocking structure 230 may be sloped with respect to the vertical direction.

Referring to FIG. 12, the blocking structure 230 may include a lower portion having a relatively large width, and an upper portion having a relatively small width.

Thus, each of the inner sidewall and the outer sidewall of the blocking structure 230 may have a staircase shape.

FIG. 12 shows that the second adhesion layer 400 does not cover an upper surface of the blocking structure 230 and contacts the outer sidewall of the blocking structure 230, however, inventive concepts are not limited thereto, and may also cover the upper surface of the blocking structure 230.

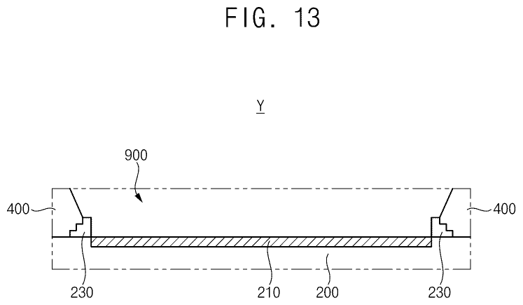

Referring to FIG. 13, the outer sidewall of the blocking structure 230 may have a staircase shape.

Thus, the blocking structure 230 may include a lower portion having a first width, a central portion having a second width less than the first width, and an upper portion having a third width less than the second width. That is, the blocking structure 230 may include three portions at three levels, respectively, that may be stacked in the vertical direction.

FIG. 13 shows that the second adhesion layer 400 does not cover an upper surface of the blocking structure 230 and contacts the outer sidewall of the blocking structure 230, however, inventive concepts are not limited thereto, and may also cover the upper surface of the blocking structure 230.

Additionally, the blocking structure 230 may include more than three portions stacked in the vertical direction, which may have a staircase shape.

As illustrated with reference to FIGS. 11 to 13, the blocking structure 230 may have various shapes in addition to that of FIG. 1. For example, the blocking structure 230 may have convex upper shape instead of a flat upper surface.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a CMOS image sensor, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of inventive concepts. Accordingly, all such modifications are intended to be included within the scope of example embodiments as defined in the claims.

What is claimed is:

1. A semiconductor package comprising:
a package substrate;
an image sensor chip on the package substrate,
the image sensor chip including an active pixel sensor (APS) region, a non-active pixel sensor (non-APS) region at least partially surrounding the APS region, and a pad region at least partially surrounding the non-APS region,
the image sensor chip including a blocking structure on the non-APS region, and an inner sidewall of the blocking structure adjacent to the APS region being at a boundary between the APS region and the non-APS region;
a first adhesion layer on the non-APS region of the image sensor chip and the pad region of the image sensor chip;
a transparent cover on the first adhesion layer; and
a molding member on the package substrate, the molding member covering a sidewall of the image sensor chip and a sidewall of the first adhesion layer.

2. The semiconductor package according to claim 1, wherein the blocking structure has a shape of a rectangular ring surrounding the APS region of the image sensor chip.

3. The semiconductor package according to claim 1, wherein the inner sidewall of the blocking structure extends in a vertical direction, and the vertical direction is perpendicular to an upper surface of the package substrate.

4. The semiconductor package according to claim 3, wherein
an outer sidewall of the blocking structure is opposite the inner sidewall of the blocking structure,
the outer sidewall of the blocking structure includes a lower portion extending in the vertical direction and an upper portion sloped with respect to the vertical direction.

5. The semiconductor package according to claim 3, wherein
an outer sidewall of the blocking structure is opposite the inner sidewall of the blocking structure, and
the outer sidewall of the blocking structure has a staircase shape.

6. The semiconductor package according to claim 1, wherein
a lower portion of the blocking structure has a first width,
an upper portion of the blocking structure has a second width, and
the second width is less than the first width.

7. The semiconductor package according to claim 1, wherein
the first adhesion layer contacts an outer sidewall of the blocking structure, and
the outer sidewall of the blocking structure is opposite the inner sidewall of the blocking structure.

8. The semiconductor package according to claim 1, wherein the blocking structure includes an insulating material.

9. The semiconductor package according to claim 1, further comprising:
a bonding wire, wherein
the image sensor chip includes a chip pad in the pad region,
the package substrate includes a substrate pad, and
wherein the bonding wire contacts the chip pad and the substrate pad.

10. The semiconductor package according to claim 9, wherein the first adhesion layer covers an upper portion of the chip pad and a portion of the bonding wire.

11. The semiconductor package according to claim 1, wherein the first adhesion layer includes glue.

12. The semiconductor package according to claim 1, further comprising:
a second adhesion layer between an upper surface of the package substrate and a lower surface of the image sensor chip.

13. A semiconductor package comprising:
a package substrate;
an image sensor chip on the package substrate,
the image sensor chip including a first region, a second region at least partially surrounding the first region, and a third region at least partially surrounding the second region,
the image sensor chip including a blocking structure,
wherein a first sidewall of the blocking structure is aligned with an edge of the first region of the image sensor in a vertical direction and the vertical direction is perpendicular to an upper surface of the package substrate,
wherein active pixels are in the first region,
wherein no active pixels are in the second region, and
wherein a chip pad is in the third region;
an adhesion layer on the second region and the third region of the image sensor chip, the adhesion layer contacting the blocking structure;
a transparent cover on the adhesion layer; and
a molding member on the package substrate, the molding member covering a sidewall of the image sensor chip and a sidewall of the adhesion layer.

14. The semiconductor package according to claim 13, wherein the blocking structure has a shape of a rectangular ring surrounding the first region of the image sensor chip.

15. The semiconductor package according to claim 13, wherein
a second sidewall of the blocking structure is opposite the first sidewall of the blocking structure, and
the second sidewall of the blocking structure is on the second region of the image sensor chip.

16. The semiconductor package according to claim 15, wherein the adhesion layer contacts the second sidewall of the blocking structure.

17. The semiconductor package according to claim 13, further comprising:
a bonding wire, wherein the package substrate includes a substrate pad,
wherein the bonding wire contacts the chip pad and the substrate pad, and
the adhesion layer covers an upper portion of the chip pad and a portion of the bonding wire.

18. A semiconductor package comprising:
a package substrate including a substrate pad;
a first adhesion layer on the package substrate;
an image sensor chip bonded to the first adhesion layer,
the image sensor chip including an active pixel sensor (APS) region, a non-active pixel sensor (non-APS) region at least partially surrounding the APS region, and a pad region at least partially surrounding the non-APS region,
the image sensor chip including a blocking structure on the non-APS region and a chip pad in the pad region,
an inner sidewall of the blocking structure being adjacent to the APS region at a boundary between the APS region and the non-APS region;
a bonding wire contacting the chip pad and the substrate pad;
a second adhesion layer on the non-APS region and the pad region of the image sensor chip, the second adhesion layer covering an upper surface of the chip pad and a portion of the bonding wire;
a transparent cover on the second adhesion layer; and
a molding member on the package substrate,
the molding member covering a sidewall of the first adhesion layer, a sidewall of the image sensor chip, and a sidewall of the second adhesion layer, and the molding member covering a portion of the bonding wire.

19. The semiconductor package according to claim 18, wherein the blocking structure has a shape of a rectangular ring surrounding the APS region of the image sensor chip.

20. The semiconductor package according to claim 18, wherein
the second adhesion layer has a shape of a rectangular ring surrounding the blocking structure, and
an upper surface of the second adhesion layer is higher than an upper surface of the blocking structure.
